(19) United States
(12) Patent Application Publication
(10) Pub. No.: US 2013/0327373 A1
(43) Pub. Date: Dec. 12, 2013

(54) AGGREGATED FRAME FOR SOLAR PHOTOVOLTAIC LAMINATES

(71) Applicant: Georgia Tech Research Corporation, Atlanta, GA (US)

(72) Inventors: Russell Gentry, Decatur, GA (US); Joseph Goodman, Atlanta, GA (US); Brian Simmons, Lawrenceville, GA (US)

(21) Appl. No.: 13/916,471

(22) Filed: Jun. 12, 2013

Related U.S. Application Data
(60) Provisional application No. 61/658,683, filed on Jun. 12, 2012.
(60) Provisional application No. 61/659,505, filed on Jun. 14, 2012.

(51) Int. Cl. H01L 31/042

(52) U.S. Cl. CPC H01L 31/0424
USPC 136/251

(57) ABSTRACT

An exemplary embodiment of the present invention provides a solar assembly comprising a frame and a plurality of solar photovoltaic laminates. The frame can substantially define a perimeter of the assembly and can comprise an elongated channel spanning an interior of at least a portion of the frame. The channel can comprise an electrical bus bar. The plurality of solar photovoltaic laminates can be positioned adjacent each other and supported and secured in place by the frame along one or more edges of the plurality of laminates. Each of the plurality of laminates can one or more bus bar leads exiting the laminate between a top encapsulate layer and a bottom encapsulate layer of the laminate on a side edge of the laminate that can be substantially adjacent a portion of the frame. Each of the bus bar leads can be electrically coupled to the bus bar.

### CROSS-REFERENCE TO RELATED APPLICATIONS

This application claims the benefit of U.S. Provisional Application Ser. No. 61/658,683, filed on 12 Jun. 2012, and U.S. Provisional Application Ser. No. 61/659,505, filed on 14 Jun. 2012, both of which are incorporated herein by reference in their entireties as if fully set forth below.

### FEDERALLY SPONSORED RESEARCH STATEMENT

This invention was made with Government support under Agreement No. DE-EE0005441, awarded by the Department of Energy. The Government has certain rights in the invention.

### TECHNICAL FIELD OF THE INVENTION

The various embodiments of the present disclosure relate generally to solar panels. More particularly, the various embodiments of the present invention are directed to systems and methods for aggregating solar photovoltaic laminates into a frame.

### BACKGROUND OF THE INVENTION

Over the past few decades, increasing focus has been given to solar power as a possible source of clean and sustainable energy. Many residential homes, as well as commercial buildings, make use of local solar panels to provide at least a portion of the power used by the home/building. Conventional solar panels include a frame enclosing the perimeter of a single photovoltaic laminate. The laminate includes a plurality of cells electrically connected with ribbons. The ribbons are electrically coupled to bus bar leads the exit the laminate via a bottom encapsulate layer of the laminate. One limiting factor in the amount of electric power a particular solar panel can generate is the size, e.g., total surface area of the cells, of the laminate. It is very difficult to alter manufacturing processes to in order to produce different size laminates. Instead, manufacturers are much more efficient when they produce a single-sized laminate. Thus, in order to increase the capacity of a local solar generation system, conventionally, multiple individual solar panels—each with a separate frame and laminate—are mounted and connected adjacent each other.

Unfortunately, the conventional method of mounting and connecting adjacent panels presents many problems. For example, it may be difficult to squarely align the individual panels on a roof, as each frame may be required to be individually mounted to the roof. Additionally, the electrical leads from adjacent panels are externally connected to finalize installation. This additional connection step presents significant problems of its own. For example, while the installation of a single panel is outside the jurisdiction of a home/building inspector because it is manufactured remotely, when multiple, individual panels are installed and connected adjacent each other, those connections cause the system to come under an inspector's jurisdiction. Moreover, because the electrical leads from each individual laminate are connected external to the panels, problems with loose cables and environmental exposure arise. Further, because the electrical leads exit the laminate through the encapsulate layer on the bottom of the laminate, it may be difficult to ensure proper connections between adjacent panels.

Therefore, there is a desire for enhanced solar panels that improve upon one or more of the problems described above. Various embodiments of the present invention address this desire.

### BRIEF SUMMARY OF THE INVENTION

The present invention relates to solar panel assemblies for aggregating multiple solar photovoltaic laminates with a shared frame. An exemplary embodiment of the present invention provides an aggregated solar assembly comprising a frame and a plurality of solar photovoltaic laminates. The frame can substantially define a perimeter of the assembly. The frame can comprise an elongated channel spanning an interior of at least a portion of the frame. The channel can comprise an electrical bus bar. The plurality of solar photovoltaic laminates can be positioned adjacent each other. The plurality of laminates can be supported and secured in place by the frame along one or more edges of the plurality of laminates. Each of the plurality of laminates can comprise a plurality of cells electrically coupled via ribbons. The ribbons can be electrically coupled to one or more bus bar leads of each of the plurality of laminates. The one or more bus bar leads can exit the laminate between a top encapsulate layer and a bottom encapsulate layer of the laminate on a side edge of the laminate. The side edge can be substantially adjacent a portion of the frame. Each of the bus bar leads can be electrically coupled to the bus bar to electrically couple the plurality of laminates to the bus bar.

In some embodiments of the present invention, at least a portion of the frame can comprise a base portion and a top cap fitted together to define the channel therebetween.

In some embodiments of the present invention, the base portion can be positioned adjacent a bottom surface of the plurality of laminates and the top cap can be positioned adjacent a top surface of the plurality of laminates.

In some embodiments of the present invention, the base portion and the top cap can fit together to form a watertight seal substantially preventing water from entering the channel.

In some embodiments of the present invention, the solar panel assembly can further comprise one or more electrical leads electrically coupled to the bus bar within the channel. In some embodiments of the present invention, at least a portion of the one or more electrical leads exits the frame. In some embodiments of the present invention, the one or more electrical leads can transmit electrical power from the solar panel assembly to a desired location.

In some embodiments of the present invention, the frame can comprise a non-conductive material.

In some embodiments of the present invention, the channel can comprise a plurality of diodes electrically coupled to one or more or the bus bar leads. In some embodiments of the present invention, the plurality of diodes can be operable to electrically isolate one or more of the plurality of laminates.

In some embodiments of the present invention, a cross-sectional area of the channel varies along a length of the channel to account for one or more components located within the channel.

In some embodiments of the present invention, the frame is of unitary construction.

Another exemplary embodiment of the present invention provides a solar panel assembly comprising a frame and a plurality of solar photovoltaic laminates. The frame can comprise first, second, third, and fourth support members. The first support member can have first and second ends. The second support member can have first and second ends and can be substantially parallel to the first support member. The third support member can have first and second ends and can be substantially perpendicular to the first and second support members, such that the first end of the third support member is coupled to the first end of the first support member and the second end of the third support member is coupled to the first end of the second support member. The fourth support member can have first and second ends and can be substantially perpendicular to the first and second support members, such that the first end of the fourth support member is coupled to the second end of the first support member and the second end of the fourth support member is coupled to the second end of the second support member. The frame can also comprise an elongated channel spanning an interior of at least a portion of the first support member. The channel can comprise an electrical bus bar. The plurality of solar photovoltaic laminates can be positioned adjacent each other and supported and secured in place by the first, second, third, and fourth support members of the frame along one or more edges of the plurality of laminates. Each of the plurality of laminates can comprise a plurality of cells electrically coupled via ribbons. The ribbons can be electrically coupled to one or more bus bar leads of each of the plurality of laminates. The one or more bus bar leads can exit the laminate between a top encapsulate layer and a bottom encapsulate layer of the laminate on a side edge of the laminate that is substantially adjacent the first support member of the frame. Each of the bus bar leads can be electrically coupled to the bus bar to electrically couple the plurality of laminates to the bus bar.

Another exemplary embodiment of the present invention provides an aggregated solar assembly comprising a frame and a plurality of solar photovoltaic laminates. The frame can comprise an elongated channel spanning an interior of at least a portion of the frame. The channel can comprise an electrical bus bar. The plurality of solar photovoltaic laminates can be positioned adjacent each other and supported and secured in place by the frame along one or more edges of the plurality of laminates. Each of the plurality of laminates can comprise one or more bus bar leads exiting the laminate between a top encapsulate layer and a bottom encapsulate layer of the laminate on a side edge of the laminate that can be substantially adjacent a portion of the frame. Each of the bus bar leads can be electrically coupled to the bus bar to electrically couple the plurality of laminates to the bus bar.

These and other aspects of the present invention are described in the Detailed Description of the Invention below and the accompanying figures. Other aspects and features of embodiments of the present invention will become apparent to those of ordinary skill in the art upon reviewing the following description of specific, exemplary embodiments of the present invention in concert with the figures. While features of the present invention may be discussed relative to certain embodiments and figures, all embodiments of the present invention can include one or more of the features discussed herein. Further, while one or more embodiments may be discussed as having certain advantageous features, one or more of such features may also be used with the various embodiments of the invention discussed herein. In similar fashion, while exemplary embodiments or features may be discussed below as device, system, or method embodiments, it is to be understood that such exemplary embodiments or features can be implemented in various devices, systems, and methods of the present invention.

### BRIEF DESCRIPTION OF THE DRAWINGS

The following Detailed Description of the Invention is better understood when read in conjunction with the appended drawings. For the purposes of illustration, there is shown in the drawings exemplary embodiments, but the subject matter is not limited to the specific elements and instrumentalities disclosed.

FIG. 1A illustrates a portion of a solar panel assembly, in accordance with an exemplary embodiment of the present invention.

FIG. 1B illustrates a cross-sectional view of a portion of the solar panel assembly shown in FIG. 1A, in accordance with an exemplary embodiment of the present invention.

FIG. 2 illustrates a solar panel assembly, in accordance with an exemplary embodiment of the present invention.

FIG. 3 illustrates a solar panel assembly, in accordance with an exemplary embodiment of the present invention.

FIGS. 4A-4D provide detailed illustrations of portions of the solar panel assembly shown in FIG. 3, in accordance with exemplary embodiments of the present invention.

### DETAILED DESCRIPTION OF THE INVENTION

To facilitate an understanding of the principles and features of the present invention, various illustrative embodiments are explained below. To simplify and clarify explanation, the invention is described below as applied to solar panel assemblies for installation on the roofs of commercial and residential buildings. One skilled in the art will recognize, however, that the invention is not so limited. Instead, as those skilled in the art would understand, the various embodiments of the present invention also find application many other areas where it is desirable to install solar panels or solar power systems.

The components, steps, and materials described hereinafter as making up various elements of the invention are intended to be illustrative and not restrictive. Many suitable components, steps, and materials that would perform the same or similar functions as the components, steps, and materials described herein are intended to be embraced within the scope of the invention. Such other components, steps, and materials not described herein can include, but are not limited to, similar components or steps that are developed after development of the invention.

As discussed above, to increase solar capacity in a single location, conventional techniques require that multiple individual solar panels be positioned adjacent to one another and connected together. As also discussed above, however, these techniques present many disadvantages. Accordingly, exemplary embodiments of the present invention provide aggregated solar panel assemblies having a plurality solar photovoltaic laminates positioned adjacent one another with a common frame. This allows a single frame to be mounted, e.g., on the roof of a building, wherein the single frame contains the desired number of laminates to achieve the desired solar power capacity. Additionally, in some embodiments of the present invention, the frame can comprise a channel with a bus bar for electrically coupling adjacent laminates, thus substantially reducing and/or eliminating the need for electrical connections outside of the solar panel assembly.

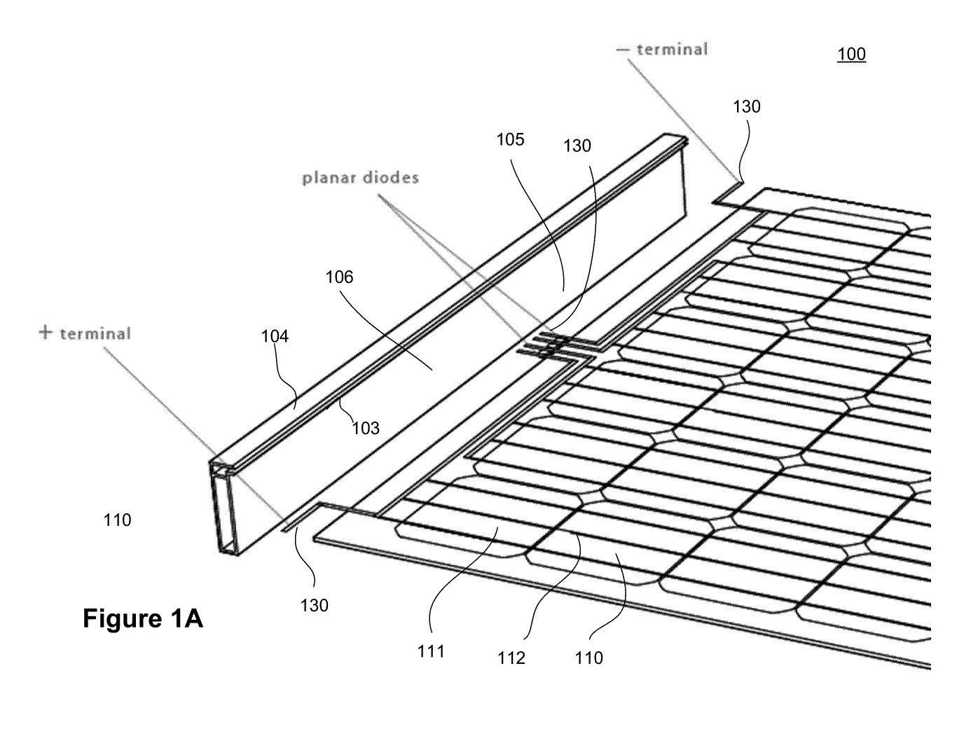

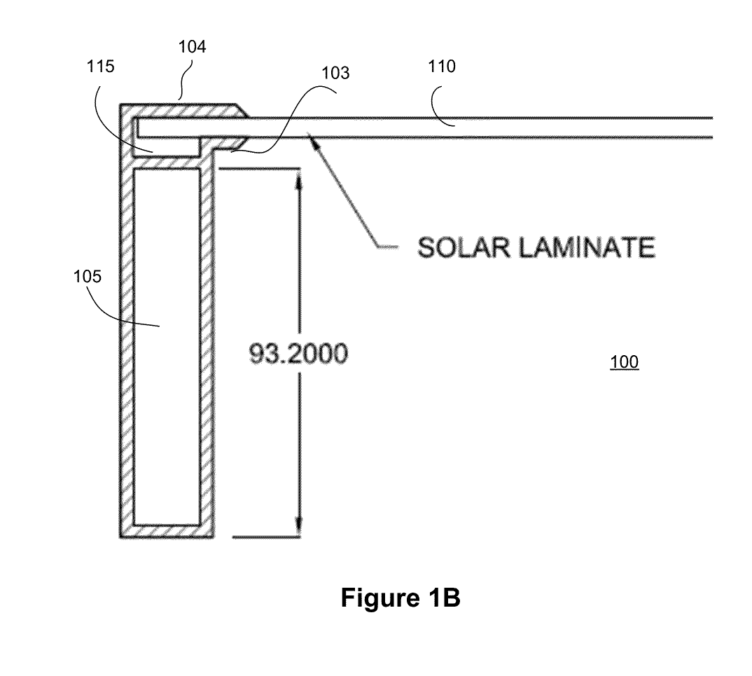

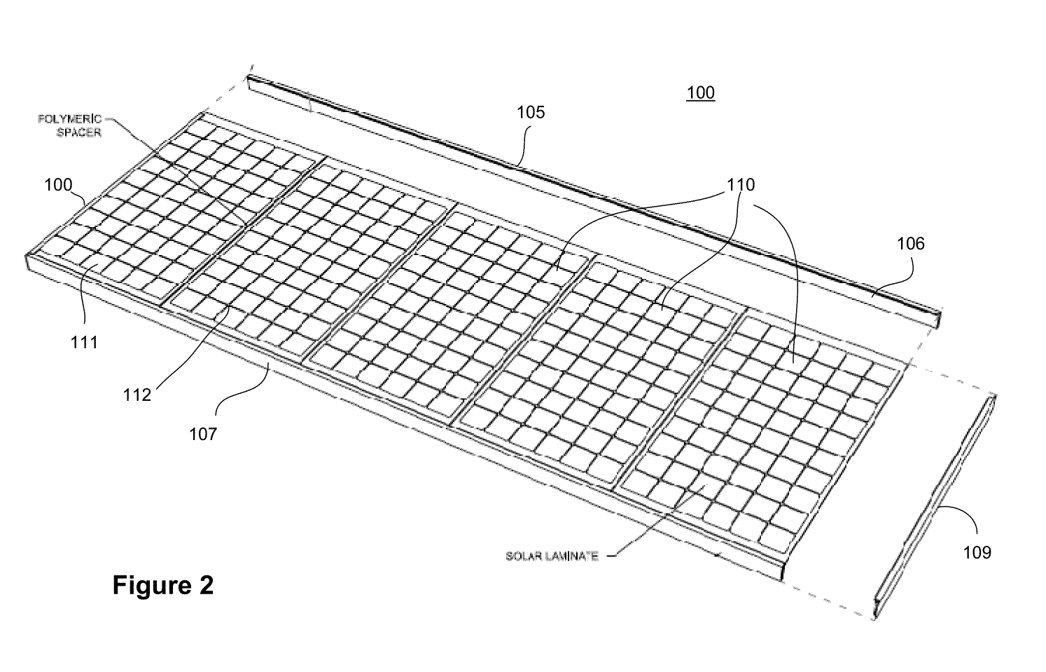

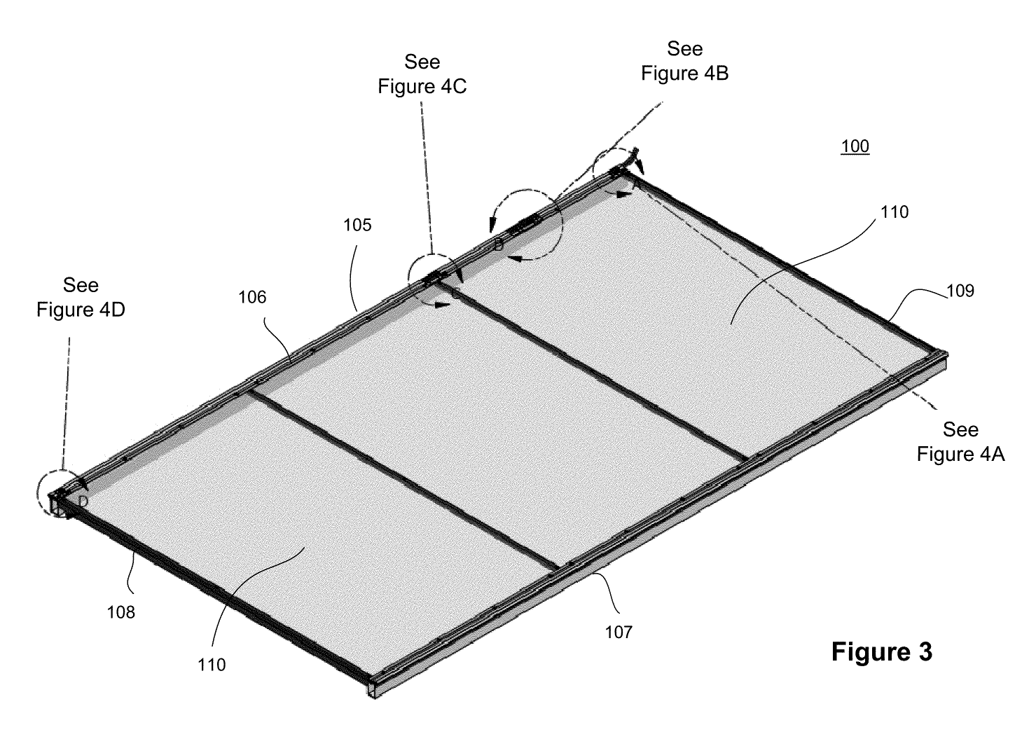

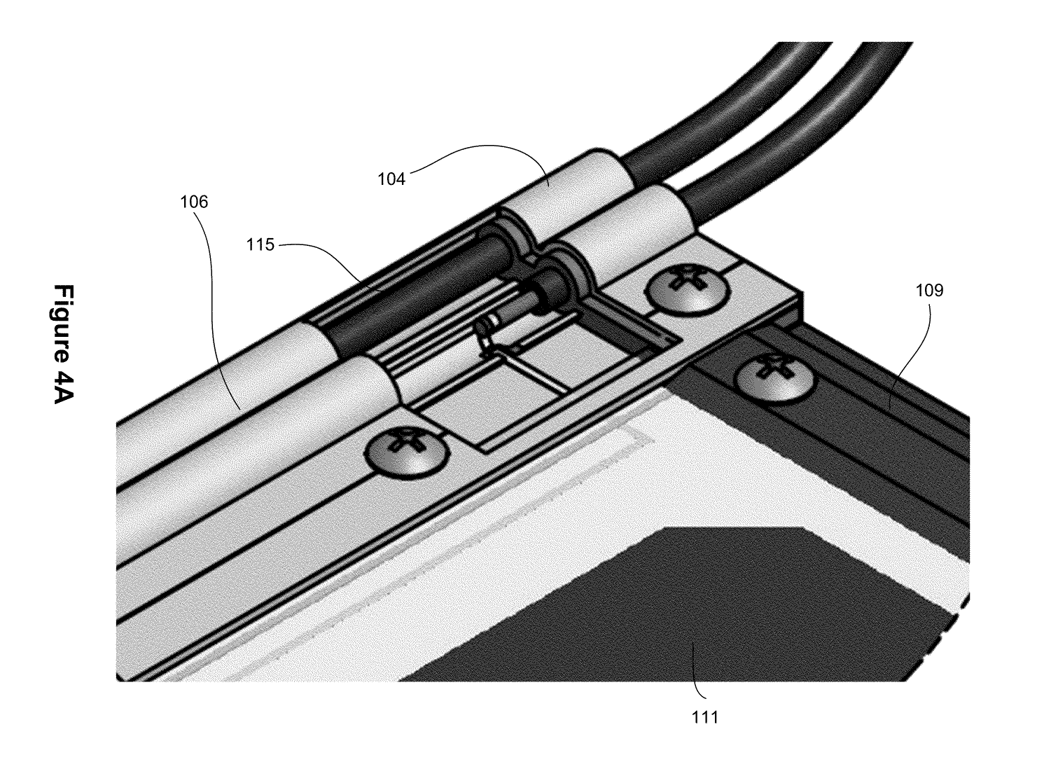

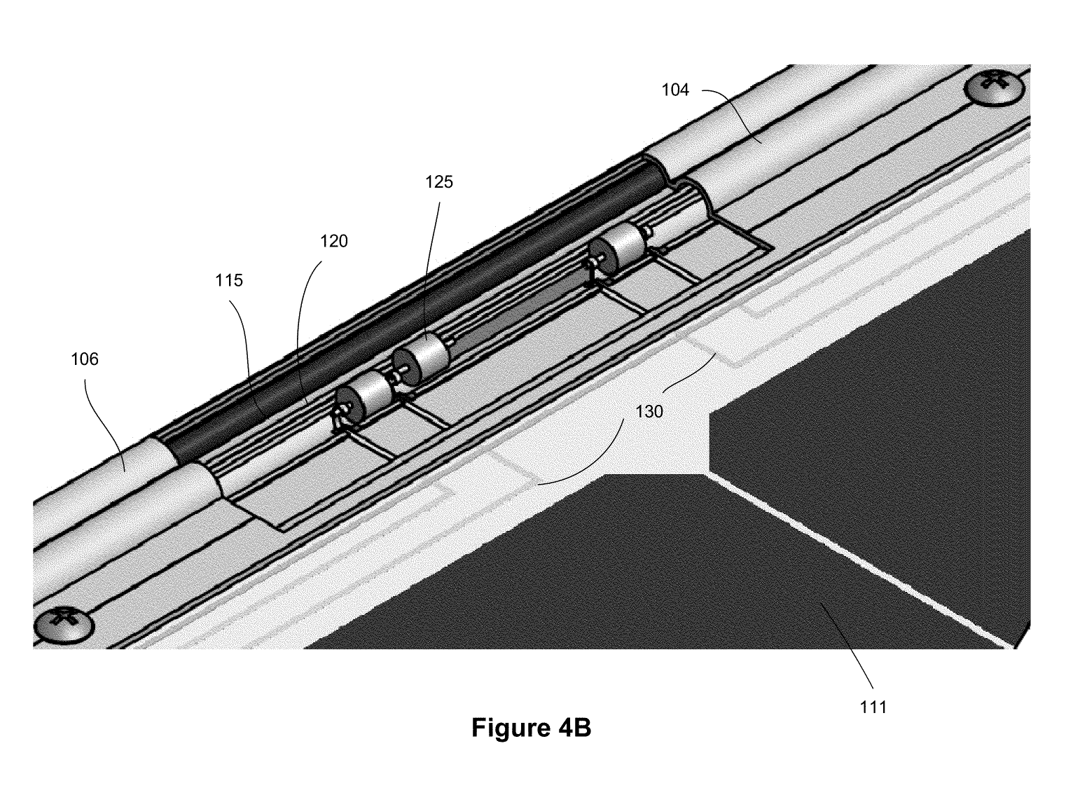

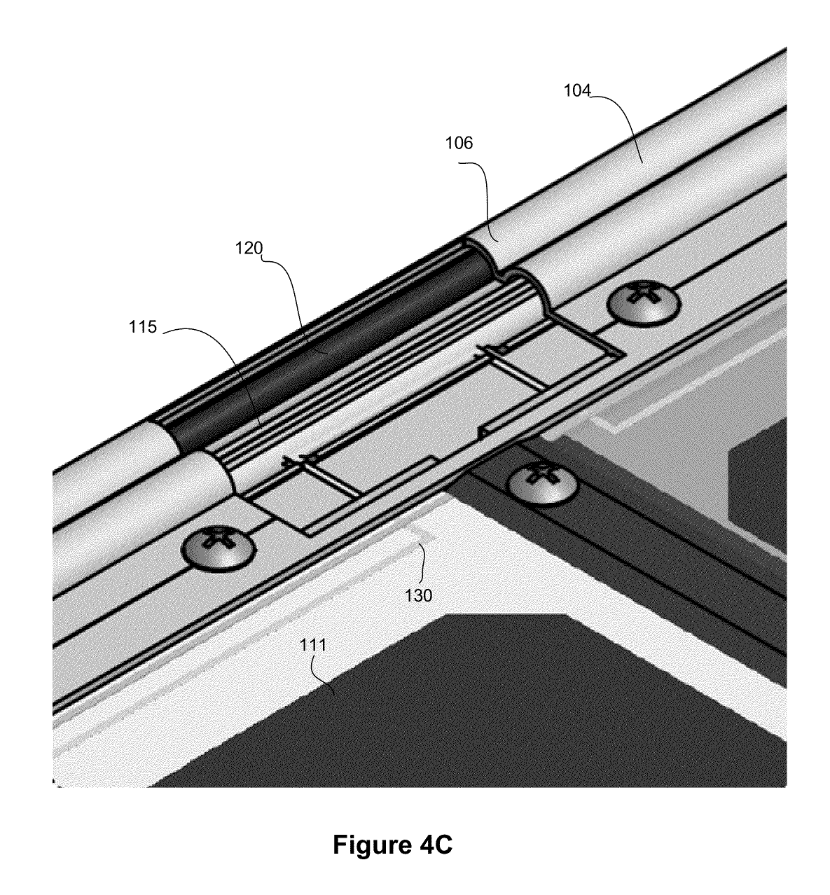

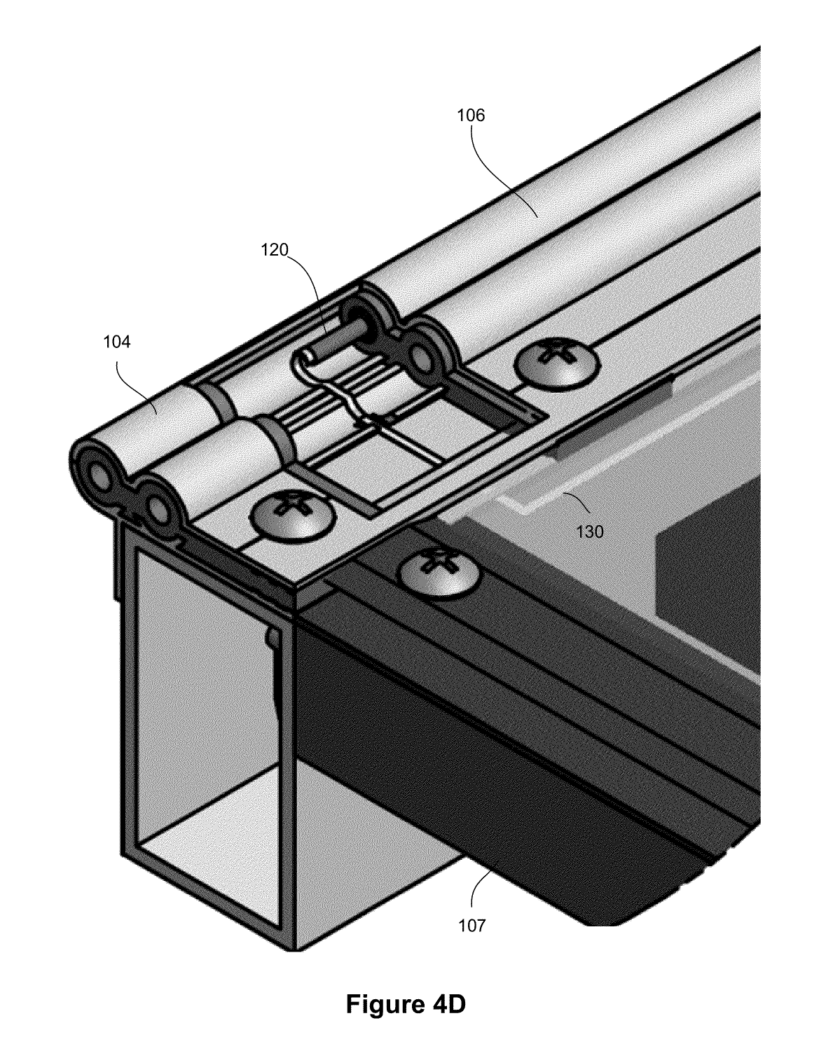

A shown in FIGS. 1-3, an exemplary embodiment of the present invention provides a solar panel assembly 100 comprising a frame 105 and a plurality of solar photovoltaic laminates 110. The plurality of laminates can be positioned adjacent one another and supported and secured in place by the frame 105 along one or more edges of the plurality of laminates 110. The frame 105 can substantially define a perimeter of the assembly. For example, as shown in FIGS. 2-3, the frame 105 can extend around the perimeter of the adjacently positioned laminates 110.

The various embodiments of the present invention can support various combinations and layouts of the laminates 110. For example, as shown in FIG. 3, the laminates 110 are arranged in a 3×1 layout. The present invention, however, is not so limited. Instead, as those skilled in the art would appreciate, the present invention can support many layouts, including, but not limited to, 2×1, 2×2, 3×2, 3×3 and the like. Those skilled in the art would also appreciate various alignments for the frame 105 to account for the various layouts contemplated herein in accordance with the spirit of the present invention.

In some embodiments of the present invention, the frame 105 can comprise an elongated channel 115 spanning an interior of at least a portion of the frame 105. The length and/or position of the channel 115 within the frame 105 can vary depending on the number and/or layout of the laminates 110. For example, in the 3×1 layout shown in FIG. 3, the channel 115 can be substantially within a portion of a first support member 106 of the frame 105. The channel 115 can comprise an electrical bus bar 120. The bus bar 120 can extend substantially along the length of the channel 115. The bus bar 120 can electrically couple one or more components connected to the bus bar 120. The bus bar 120 can also contain one or more components forming an electrical circuit. For example, in some embodiments of the present invention, the channel 115 can comprise one or more diodes 125 electrically coupled to the bus bar 120. The one or more diodes 125 can be used to control or isolate, e.g., turn on and off, one or more laminates 110 or portions of the laminates 110. Additionally, in some embodiments of the present invention, the cross-sectional shape and/or area of the channel 115 can vary along the length of the channel 115 to account for the one or more components contained within the channel 115.

Each of the plurality of laminates 110 can comprise a plurality of photovoltaic cells 111. The cells 111 can be electrically coupled via ribbons 112. The ribbons 112 can be electrically coupled to one or more bus bar leads 130 of the laminate 110 for a particular ribbon 112. The laminate 110 can comprise top and bottom encapsulate layers. The cells 111 and ribbons 112 can be positioned between the top and bottom encapsulate layers. Additionally, the bus bar leads 130 can be positioned between the top and bottom encapsulate layers. In each laminate 110, the bus bar leads 130 can exit the laminate 110 between the top encapsulate layer and the bottom encapsulate layer on a side edge of the laminate. The bus bar leads 130 can exit the laminate 110 via a side edge that is adjacent the frame 105. In an exemplary embodiment of the present invention, the bus bar leads 130 exit the laminate 110 via a side edge that is adjacent the portion of the frame 105 comprising the channel 115. The bus bar leads 130 can be electrically coupled to the bus bar 120 to electrically couple the plurality of laminates 110 together. In some embodiments, the bus bar leads 130 can be electrically coupled to the bus bar 120 via one or more diodes 125, thus enabling control and/or isolation of one or more laminates 110 or portions of the laminates 110.

As shown in FIG. 1B, in some embodiments of the present invention, a portion of the frame 105 comprises a base portion 103 and a top cap 104. The base portion 103 and top cap 104 can be fitted together to define the channel 115 therebetween. In some embodiments, the base portion 103 is positioned adjacent the bottom surfaces of the plurality of laminates 110 and the top cap 104 is positioned adjacent the top surfaces of the plurality of laminates 110, such that the laminates 110 can be secured in place via opposing forces from the base portion 103 and top cap 104. In some embodiments of the present invention, the base portion 103 and top cap 104 fit together with each other and/or one or more of the laminates 110 to form a watertight seal, thus substantially preventing water or other liquids from entering the channel 115. In some embodiments of the present invention, an agent is used at the bonding site of the base portion 103 and the top cap 104, which may aid in forming the watertight seal therebetween. The agent can be many agents known in the art, including, but not limited to, rubbers, polymers, hydrophobic agents, water resistant agents, and the like.

The frame 105 can comprise many different materials known in the art. In an exemplary embodiment of the present invention, the frame 105 comprises a non-conductive material. Such a non-conductive material can limit the need for grounding circuits for the assembly. In some embodiments of the present invention, the frame 105 can be of unitary construction, i.e., made of a single piece of material. In some embodiments of the present invention, each element of the frame 105, except the top cap 104, is of unitary construction. For example, one or more members/components of the frame 105 can be molded forming a single piece.

The frame 105 can be many different sizes and shapes to account for the various layouts and orientations of the plurality of laminates 110. For example, as shown in FIG. 3, in some embodiments of the present invention, the frame 105 can be rectangular-shaped. The frame 105 can comprise a first 106, second 107, third 108, and fourth 109 support member, each having first and second ends. The second support member 107 can be substantially parallel to the first support member 106. The third support member 108 can be substantially perpendicular to the first 106 and second 107 support members with the first end of the third support member 108 coupled to the first end of the first support member 106 and the second end of the third support member 108 coupled to the first end of the second support member 107. The fourth support member 109 can be substantially perpendicular to the first 106 and second 107 support members with the first end of the fourth support member 109 coupled to the second end of the first support member 106 and the second end of the fourth support member 109 coupled to the second end of the second support member 107. The elongated channel 115 can span an interior of at least a portion of the first support member 106. The one or more bus bar leads 130 of the plurality of laminates 110 can exit the laminate 110 between a top encapsulate layer and a bottom encapsulate layer of the laminate 110 on a side edge of the laminate 110 substantially adjacent the first support member 106 of the frame 105.

In some embodiments of the present invention, the first support member 106 comprises a base portion 103 and a top cap 104 fitted together to define the channel 115 therebetween. In some embodiments of the present invention, other support members can comprise a base portion 103 and top cap 104 fitted together to define the channel 115 therebetween. Thus, in some embodiments of the present invention, the channel 115 can extend along more than one side/edge of the frame 105.

In some embodiments of the present invention, one or more of the support members of the frame 105 can be of unitary construction. In an exemplary embodiment of the present invention, at least a portion of each of the support members is of unitary construction. For example, in some embodiments of the present invention, the second 107, third 108, and fourth 109 support members and the base portion 103 of the first support member 106 are of unitary construction. In some embodiments of the present invention, the base portion 103 of the first 106, second 107, third 108, and fourth 109 support members are of unitary construction. In some embodiments of the present invention, the base portion 103 of the first 106 and second 107 support members and the third 108 and fourth 109 support members are of unitary construction.

It is to be understood that the embodiments and claims disclosed herein are not limited in their application to the details of construction and arrangement of the components set forth in the description and illustrated in the drawings. Rather, the description and the drawings provide examples of the embodiments envisioned. The embodiments and claims disclosed herein are further capable of other embodiments and of being practiced and carried out in various ways. Also, it is to be understood that the phraseology and terminology employed herein are for the purposes of description and should not be regarded as limiting the claims.

Accordingly, those skilled in the art will appreciate that the conception upon which the application and claims are based may be readily utilized as a basis for the design of other structures, methods, and systems for carrying out the several purposes of the embodiments and claims presented in this application. It is important, therefore, that the claims be regarded as including such equivalent constructions.

Furthermore, the purpose of the foregoing Abstract is to enable the United States Patent and Trademark Office and the public generally, and especially including the practitioners in the art who are not familiar with patent and legal terms or phraseology, to determine quickly from a cursory inspection the nature and essence of the technical disclosure of the application. The Abstract is neither intended to define the claims of the application, nor is it intended to be limiting to the scope of the claims in any way. Instead, it is intended that the invention is defined by the claims appended hereto.

What is claimed is:

1. A solar assembly, comprising:
a frame substantially defining a perimeter of the assembly, the frame comprising an elongated channel spanning an interior of at least a portion of the frame, the channel comprising an electrical bus bar; and
a plurality of solar photovoltaic laminates positioned adjacent each other, the plurality of laminates supported and secured in place by the frame along one or more edges of the plurality of laminates,
wherein each of the plurality of laminates comprises a plurality of cells electrically coupled via ribbons, the ribbons electrically coupled to one or more bus bar leads of each of the plurality of laminates, the one or more bus bar leads exiting the laminate between a top encapsulate layer and a bottom encapsulate layer of the laminate on a side edge of the laminate, the side edge substantially adjacent a portion of the frame,
wherein each of the bus bar leads is electrically coupled to the bus bar to electrically couple the plurality of laminates to the bus bar.

2. The solar panel assembly of claim 1, wherein at least a portion of the frame comprises a base portion and a top cap fitted together to define the channel therebetween.

3. The solar panel assembly of claim 2, wherein the base portion is positioned adjacent a bottom surface of the plurality of laminates and the top cap is positioned adjacent a top surface of the plurality of laminates.

4. The solar panel assembly of claim 3, wherein the base portion and the top cap fit together to form a watertight seal substantially preventing water from entering the channel.

5. The solar panel assembly of claim 1, further comprising one or more electrical leads electrically coupled to the bus bar within the channel, at least a portion of the one or more electrical leads exiting the frame, the one or more electrical leads for providing transmitting electrical power from the solar panel assembly to a desired location.

6. The solar panel assembly of claim 1, wherein the frame comprises a non-conductive material.

7. The solar panel assembly of claim 1, wherein the channel comprises a plurality of diodes electrically coupled to one or more or the bus bar leads, the plurality of diodes operable to electrically isolate one or more of the plurality of laminates.

8. The solar panel assembly of claim 1, wherein a cross-sectional area of the channel varies along a length of the channel to account for one or more components located within the channel.

9. The solar panel assembly of claim 1, wherein the frame if of unitary construction.

10. A solar panel assembly, comprising:
a frame comprising:
a first support member having first and second ends;
a second support member having first and second ends, the second support member substantially parallel to the first support member;
a third support member having first and second ends, the third support member substantially perpendicular to the first and second support members, such that the first end of the third support member is coupled to the first end of the first support member and the second end of the third support member is coupled to the first end of the second support member;
a fourth support member having first and second ends, the fourth support member substantially perpendicular to the first and second support members, such that the first end of the fourth support member is coupled to the second end of the first support member and the second end of the fourth support member is coupled to the second end of the second support member; and
an elongated channel spanning an interior of at least a portion of the first support member, the channel comprising an electrical bus bar; and
a plurality of solar photovoltaic laminates positioned adjacent each other, the plurality of laminates supported and secured in place by the first, second, third, and fourth support members of the frame along one or more edges of the plurality of laminates,
wherein each of the plurality of laminates comprises a plurality of cells electrically coupled via ribbons, the ribbons electrically coupled to one or more bus bar leads of each of the plurality of laminates, the one or more bus bar leads exiting the laminate between a top encapsulate layer and a bottom encapsulate layer of the laminate on a side edge of the laminate, the side edge substantially adjacent the first support member of the frame, and
wherein each of the bus bar leads is electrically coupled to the bus bar to electrically couple the plurality of laminates to the bus bar.

11. The solar panel assembly of claim 10, wherein at least a portion of the frame comprises a base portion and a top cap fitted together to define the channel therebetween.

12. The solar panel assembly of claim 11, wherein the base portion is positioned adjacent a bottom surface of the plurality of laminates and the top cap is positioned adjacent a top surface of the plurality of laminates.

13. The solar panel assembly of claim 12, wherein the base portion and the top cap fit together to form a watertight seal substantially preventing water from entering the channel.

14. The solar panel assembly of claim 10, further comprising one or more electrical leads electrically coupled to the bus bar within the channel, at least a portion of the one or more electrical leads exiting the frame, the one or more electrical leads for providing transmitting electrical power from the solar panel assembly to a desired location.

15. The solar panel assembly of claim 10, wherein the frame comprises a non-conductive material.

16. The solar panel assembly of claim 10, wherein the channel comprises a plurality of diodes electrically coupled to one or more or the bus bar leads, the plurality of diodes operable to electrically isolate one or more of the plurality of laminates.

17. The solar panel assembly of claim 10, wherein a cross-sectional area of the channel varies along a length of the channel to account for one or more components located within the channel.

18. The solar panel assembly of claim 10, wherein the first, second, third, and fourth support members are of unitary construction.

19. An aggregated solar assembly, comprising:
a frame comprising an elongated channel spanning an interior of at least a portion of the frame, the channel comprising an electrical bus bar; and
a plurality of solar photovoltaic laminates positioned adjacent each other, the plurality of laminates supported and secured in place by the frame along one or more edges of the plurality of laminates,
wherein each of the plurality of laminates comprises one or more bus bar leads exiting the laminate between a top encapsulate layer and a bottom encapsulate layer of the laminate on a side edge of the laminate, the side edge substantially adjacent a portion of the frame,
wherein each of the bus bar leads is electrically coupled to the bus bar to electrically couple the plurality of laminates to the bus bar.
